(19) United States
(12) Patent Application Publication
(10) Pub. No.: US 2019/0019969 A1
(43) Pub. Date: Jan. 17, 2019

(54) DISPLAY DEVICE

(71) Applicant: Futaba Corporation, Mobara-shi (JP)

(72) Inventors: Yuki HIROTA, Mobara-shi (JP); Teiji KANNO, Kitaibaraki-shi (JP); Yuji AIDA, Kitaibaraki-shi (JP)

(21) Appl. No.: 16/031,547

(22) Filed: Jul. 10, 2018

(30) Foreign Application Priority Data
Jul. 11, 2017 (JP) 2017-135598

(51) Int. Cl. H01L 51/50; H01L 27/32; H01L 51/52; H01L 51/00; G09G 3/3208

(52) U.S. Cl. CPC H01L 51/504; H01L 27/3288; H01L 51/5206; G09G 2320/0233; H01L 51/0096; G09G 3/3208; G09G 2320/064; H01L 51/5221

(57) ABSTRACT

In the display device according to the present disclosure, three segments have the same total areas which are sum of the area of the lower electrode and the area of the cover wiring, and response speeds of the three segments are the same when the drive current is supplied. Since there is no difference in response speeds to the drive current between the segments, even if luminance adjustment is performed by a pulse width modulation, the luminance difference between the segments does not occur.

### CROSS-REFERENCE TO RELAYED APPLICATIONS

This application is based upon and claims the benefit of priority from Japanese Patent Application No. 2017-135598, filed on 11 Jul., 2017, the entire contents of which are incorporated herein by reference.

### TECHNICAL FIELD

The present disclosure relates to a display device.

### BACKGROUND

Recent years, as a display device, a self-luminous display device using an organic electro-luminescence (EL) layer as a light emitting layer is attracting attention. As such a display device, a segment-display type display device is known, in which a plurality of display elements (so-called segments) having a laminate structure including the organic EL layer are arranged in a display area. In the segment-display type display device, when drive current is supplied to each segment from a drive circuit via a predetermined wiring, the organic EL layer in each segment emits light, and each segment lights up. For example, in Japanese Unexamined Patent Publication No. 2016-100126, a segment-display type organic EL panel having a see-through structure is disclosed.

### SUMMARY

In the segment-display type display device described above, a positive electrode and a negative electrode are arranged to face each other in a segment area and a wiring area, and thus, a capacitive component (so-called stray capacitance) that is unintended in design are generated in those areas. The inventors obtained findings that such stray capacitance influences a response speed to the drive current to the segment and causes a difference in response speed to the drive current between the segments.

In case that the difference in response speed between the segments is large, for example, when a luminance control is performed by a pulse width modulation (PWM), the luminance of the segment in which the response speed to the drive current is low may be significantly decreased.

According to the present disclosure, there is provided a display device in which the difference in response speed to the drive current between the segments is decreased.

According to an aspect of the present disclosure, a display device is a segment type display provided with a display area on a substrate, the display device comprising: a plurality of lower electrodes positioned within the display area on the substrate; a plurality of organic EL layers provided on the plurality of lower electrodes respectively; a drive circuit capable to output a drive current to be supplied to each of the organic EL layers provided on the lower electrode; a plurality of wirings formed on the substrate, the wirings supplying the drive current output from the drive circuit to each of the lower electrodes; an insulating film covering the wirings, the insulating film formed within the display area and including a plurality of opening portions exposing each of the organic EL layers; and an upper electrode covering the insulating film and the organic EL layers, the upper electrode formed within the display area, wherein a sum of an area of a first lower electrode among the plurality of lower electrodes and an area of a first wiring connected to the first lower electrode among the plurality of wirings in the display area is the same as a sum of an area of a second lower electrode different from the first lower electrode among the plurality of lower electrodes and an area of a second wiring connected to the second lower electrode among the plurality of wirings in the display area.

The inventors newly found a fact that the difference in response speeds to the drive current between the segments is decreased in case that the sum of the area of the first lower electrode and the area of the first wiring in the display area is the same as the sum of the area of the second lower electrode and the area of the second wiring in the display area. That is, in the display device above, the difference in response speeds to the drive current between the segments can be decreased. Hence the luminance difference between the segments due to the difference in response speeds to the drive current can be decreased.

In the display device according to another aspect of the present disclosure, a ratio of the area of the first lower electrode to the area of the first wiring in the display area is the same as a ratio of the area of the second lower electrode to the area of the second wiring in the display area. In this case, the difference in response speeds to the drive current between the segments is further decreased, and thus, the luminance difference between the segments can be further decreased.

According to still another aspect of the present disclosure, a display device is a segment type display provided with a display area on a substrate, the display device comprising: a plurality of lower electrodes positioned within the display area on the substrate; a plurality of organic EL layers provided on the plurality of lower electrodes respectively; a drive circuit capable to output a drive current to be supplied to each of the organic EL layers provided on the lower electrode; a plurality of wirings formed on the substrate, the wirings supplying the drive current output from the drive circuit to each of the lower electrodes; an insulating film covering the wirings, the insulating film formed within the display area and including a plurality of opening portions exposing each of the organic EL layers; and an upper electrode covering the insulating film and the organic EL layers, the upper electrode formed within the display area, wherein a ratio of an area of a first lower electrode among the plurality of lower electrodes to an area of a first wiring connected to the first lower electrode among the plurality of wirings in the display area is the same as a ratio of an area of a second lower electrode different from the first lower electrode among the plurality of lower electrodes to an area of a second wiring connected to the second lower electrode among the plurality of wirings in the display area.

The inventors newly found a fact that the difference in response speeds to the drive current between the segments is decreased in case that the ratio of the area of the first lower electrode to the area of the first wiring in the display area is the same as the ratio of the area of the second lower electrode to the area of the second wiring in the display area. That is, in the display device above, the difference in response speeds to the drive currents between the segments can be decreased. Therefore, the luminance difference between the segments due to the difference in response speeds to the drive current can be decreased.

In the display device according to still another aspect of the present disclosure, the drive circuit capable of outputting drive currents having current values different from each other to the plurality of lower electrodes.

In the display device according to still another aspect of the present disclosure, the insulating film is an inorganic insulating film made of an inorganic material. In the inorganic insulating film, thinning the insulating film is easy, and thus, thinning the insulating film leads to the increase of the stray capacitance generated between the lower electrode and the wiring, and the upper electrode. In this case also, if the area of the first lower electrode and the area of the first wiring in the display area, and the area of the second lower electrode and the area of the second wiring in the display area satisfy the relationships described above, the difference in response speeds between the segments can be decreased. Therefore, the luminance difference between the segments due to the difference in response speeds can be effectively decreased.

### BRIEF DESCRIPTION OF THE DRAWINGS

FIG. 1 is a plan view showing a display device according to an embodiment.

FIG. 2 is a plan view in which a negative electrode and an insulating film of the display device in FIG. 1 are omitted.

FIG. 3 is a cross-sectional view of the display device in FIG. 1.

FIG. 4A and FIG. 4B are graphs showing transient behaviors of the current supplied to the segment.

### DETAILED DESCRIPTION

Hereinafter, an embodiment will be described in detail with reference to the drawings. In the description below, the same reference numerals will be given to the same elements or elements having the same function, and the descriptions thereof will not be repeated.

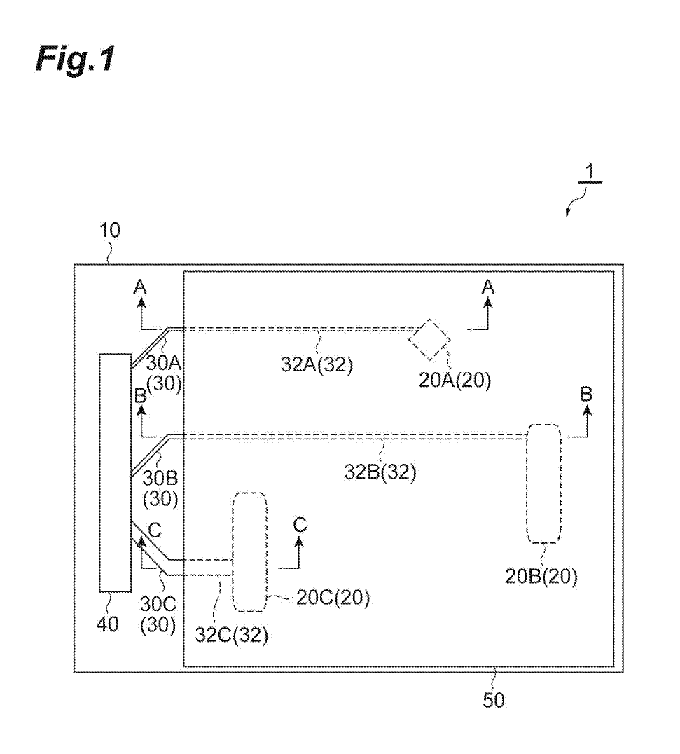

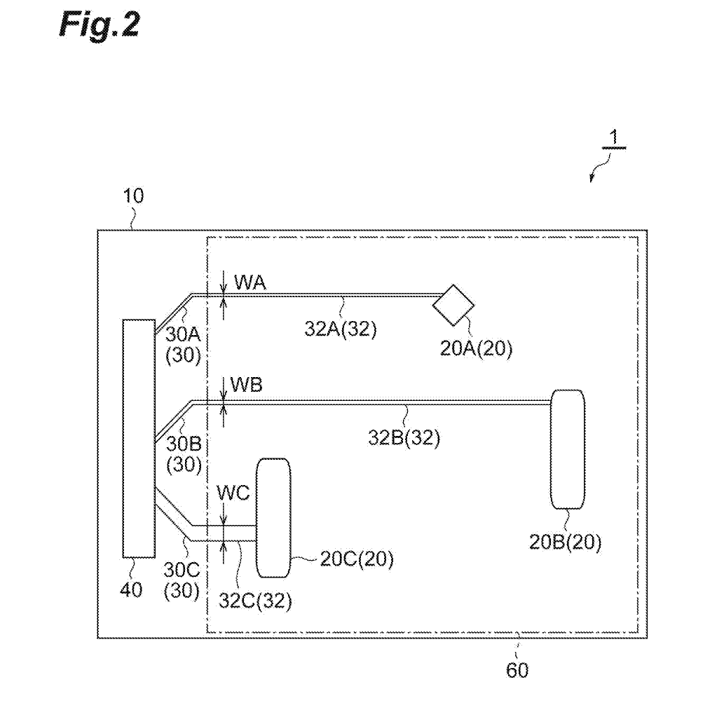

As shown in FIG. 1 and FIG. 2, a display device 1 in the embodiment is a so-called segment-display type organic EL display that includes a plurality of segments 20 (in this embodiment, three segments 20A, 20B, and 20C) in a display area 60 provided on a substrate 10. The segment 20 can represent, for example, a figure, a symbol, a letter, a number, an icon, or the like, and can represent predetermined information with one or a plurality of combinations thereof. Each segment 20 lights up when a predetermined drive current is supplied from a drive circuit 40 via a wiring 30 provided on the substrate 10. In the present embodiment, the display device 1 is a static drive type display device in which one wiring 30 is attached to one segment 20. In addition, the display device 1 has a see-through structure.

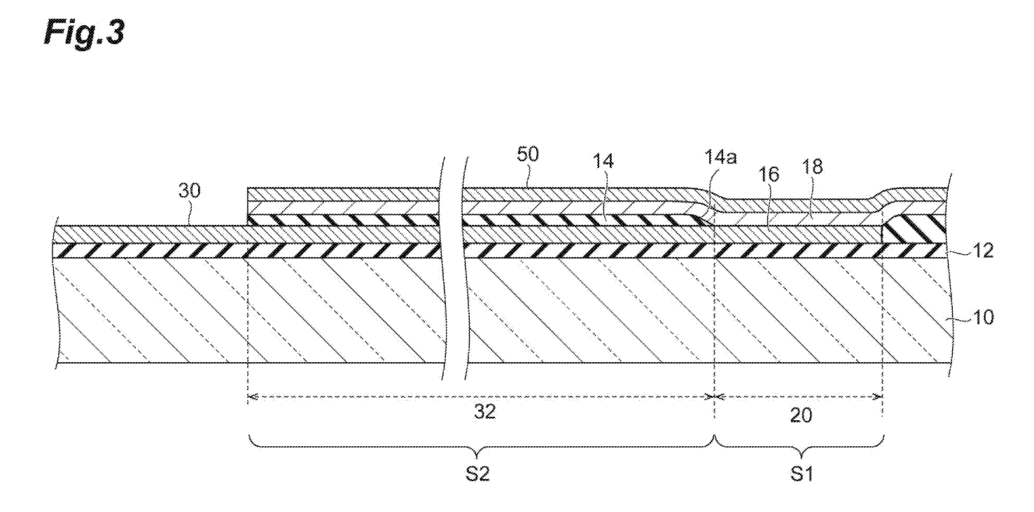

A laminate structure of the display device 1 will be described with reference to the sectional view in FIG. 3. FIG. 3 is a cross-sectional view corresponding to a cross section taken along the line A-A, line B-B, and line C-C in FIG. 1.

The substrate 10 has transparency and has, for example, a rectangular shape in planar view. For example, a glass substrate or a plastic substrate can be used as the substrate 10. The substrate 10 may have flexibility. In this case, for example, a resin film such as a PET film (a polyethylene terephthalate film) or a PI film (a polyimide film) can be used as the substrate 10.

A first insulating film 12 is a transparent film provided so as to entirely cover one main surface of the substrate 10. The first insulating film 12 is, for example, a silicon oxide film, a silicon nitride film, a silicon oxynitride film, an aluminum oxide film, or the like. The first insulating film 12 can be formed by, for example, a chemical vapor deposition (CVD) method.

A lower electrode 16 is a positive electrode provided on the first insulating film 12 and in the region of each segment 20. The lower electrode 16 is formed with a patterned transparent conductive layer. The transparent conductive layer may be a single layer or may be a plurality of layers. As a material for the transparent conductive layer, for example, indium tin oxide (ITO) or indium zinc oxide (IZO) can be used. The lower electrode 16 can be formed by, for example, a physical vapor deposition (PVD) method.

The wiring 30 is a linear-shape conductive pattern formed on the first insulating film 12 and extending to the lower electrode 16 from the drive circuit 40. As well as the lower electrode 16, the wiring 30 can also be formed with a patterned transparent conductive layer. The transparent conductive layer may be a single layer or may be a plurality of layers. As a material for the transparent conductive layer, for example, indium tin oxide (ITO) or indium zinc oxide (IZO) can be used. The wiring 30 can be formed by, for example, a physical vapor deposition (PVD) method. The lower electrode 16 may be formed with the same material as the wiring 30, and the lower electrode 16 may be integrally formed with the wiring 30.

A portion of the wiring 30 which is positioned within the display area 60 is covered with a second insulating film 14, an organic EL layer 18 and all upper electrode 50 which will be described later, and in the description below, the portion of the wiring 30 positioned within the display area 60 is also referred to as a cover wiring 32.

The second insulating film 14 (an insulating film) is a film provided on the first insulating film 12 and the wiring 30 within the display area 60. The second insulating film 14 is a transparent film and is an inorganic insulating film formed with an inorganic material such as silicon oxide, silicon nitride, silicon oxynitride, aluminum oxide or the like. The second insulating film 14 can be formed by, for example, a CVD method. An opening portion 14a corresponding to the region of forming the lower electrode 16 (that is, the region of the segment 20) is provide on the second insulating film 14. The entire surface (or substantially the entire surface) of the lower electrode 16 is exposed from the opening portion 14a of the second insulating film 14. The opening portion 14a can be provided by, for example, patterning using a resist mask.

The organic EL layer 18 is provided on the second insulating film 14 and is in contact with the lower electrode 16 at the opening portion 14a of the second insulating film 14. The organic EL layer 18 is a layer containing at least an organic compound (light emitting material) that emits light when electrons and holes are implanted. The organic compound may be a low molecular compound or a high molecular compound. The organic EL layer 18 may have an electron implantation layer, an electron transport layer, a hole implantation layer, a hole transport layer, and the like in addition to the light emitting layer containing the light emitting material. The light generated by the organic EL layer 18 may be monochromatic light such as red light or blue light or may be white light. If the organic EL layer 18 presents the white light, the organic EL layer 18 may include a plurality of light-emitting layers that emit the light of other colors. The organic EL layer 18 can be formed by a dry method such as a vacuum deposition method or a wet method such as an inkjet method. In the present embodiment, the organic EL layer 18 is formed by the dry method. The light emitting material may be a fluorescent material or may be a phosphorescent material.

The upper electrode 50 is a negative electrode formed over the entire area of the display area 60. The upper electrode 50 is provided so as to be in contact with the organic EL layer 18. The upper electrode 50 is configured as a transparent conductive layer. The transparent conductive layer may be a single layer or may be a plurality of layers. As the material for the transparent conductive layer, for example, indium tin oxide (ITO) or indium zinc oxide (IZO) can be used. The upper electrode 50 can be formed by the PVD method similarly to the lower electrode 16.

The drive circuit 40 is provided on the substrate 10 and outputs the drive current to be supplied to the organic EL layer 18 of each segment 20. The drive circuit 40 is connected to each wiring 30, and supplies the drive current to each segment 20 via each wiring 30. In the present embodiment, the drive circuit 40 can output the drive current having different current value to each segment 20. The drive circuit 40 can be connected to an external device such as a power supply or a current control circuit via a wiring such as a flexible print substrate (not shown). The drive circuit 40 does not necessarily need to be provided on the substrate 10, and may be provided on a member different from the substrate 10 if necessary, and may be connected to each wiring 30 on the substrate 10 using the flexible printed substrate or the like.

The display device 1 may have a sealing structure in which the display area 60 is sealed. As the sealing structure, a known sealing structure can be adopted, and members such as a sealing plate and a sealing material can be used.

Next, the relationship between an area S1 of the lower electrode 16 in the display device 1 and an area S2 of the cover wiring 32 will be described.

In the present embodiment, the three segments 20A, 20B, and 20C have shapes and sizes different from each other respectively, and thus, have areas different from each other. Therefore, the three lower electrodes 16 respectively corresponding to the segments 20A, 20B, and 20C have areas S1 different from each other.

In addition, the routing lengths of the cover wirings 32A, 32B, and 32C of the wirings 30A, 30B, 30C respectively connected to the three segments 20A, 20B, and 20C, which are routing lengths in the display area 60, are different from each other. In addition, line widths WA, WB, and WC of the three cover wirings 32A, 32B, and 32C are also different from each other. Therefore, the three cover wirings 32 also have areas S2 different from each other.

The inventors newly found a fact that the difference in response speeds to the drive current between the three segments 20A, 20B and 20C can be decreased by making a sum of the area S1 of the lower electrode 16 and the area S2 of the cover wiring 32 connected to the lower electrode 16 be the same (or substantially the same).

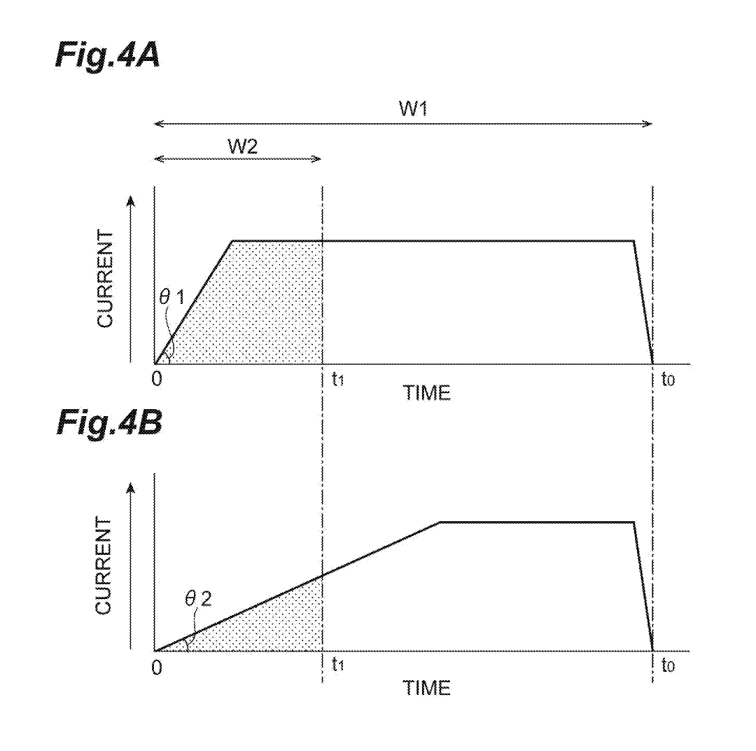

Here, a transient behavior of the current when the pulse shaped drive current is supplied to the segment 20 will be described with reference to FIG. 4A and FIG. 4B.

FIG. 4A shows a transient behavior when the drive current is supplied to the segment 20 if the sum (total area S, S1+S2) of the area S1 of the lower electrode 16 and the area S2 of the cover wiring 32 connected to the lower electrode 16 is small. FIG. 4B shows a transient behavior when the drive current is supplied to the segment 20 if the total area S is large. In the graphs in FIG. 4A and FIG. 4B, the vertical axis represents the current value supplied to the segment 20, and the horizontal axis represents an elapsed time from the timing when the current is supplied.

As shown in FIG. 4A, when the total area S is small, the response speed of the current is high. That is, the current reaches a set current in a short time, and the inclination angle θ1 of the rising current is large. On the other hand, as shown in FIG. 4B, when the total area S is large, the current response speed becomes relatively low. That is, the time for the current to reach the set current becomes long, and the inclination angle θ2 of the rising current becomes small (θ1>θ2).

As described above, the total area S influences the transient behavior of the current supplied to the segment 20, and particularly, influences the response speed of the current. Specifically, as the total area S increases, the response speed decreases accordingly. This is considered to be due to the stray capacitance generated between the upper electrode 50, and the lower electrode 16 and the cover wiring 32 facing the upper electrode 50 as shown in FIG. 3. That is, when the total area S which sum of the area S1 of the lower electrode 16 and the area S2 of the cover wiring 32 increases, the stray capacitance increases in proportion to the increase of the area, and it is considered that the increase of the stray capacitance is a factor of decrease of the response speed.

When the response speed decreases, the luminance may significantly be decreased when a luminance control is performed by the pulse width modulation. For example, as shown in FIG. 4A and FIG. 4B, when the pulse width is narrowed from the full width W1 (0→t₀) to the ¼ width W2 (0→t₁) by the pulse width modulation, there is a possibility that the current value may not reach the set current at the time t1. In this case, the luminance further decreases to a luminance lower than the luminance decreased by the pulse width modulation.

Therefore, in the present embodiment, by designing the device in such a manner the total area S of each segment 20 to be the same, the transient behavior of the current supplied to each segment 20 becomes the same. Specifically, by adjusting the line width WA, WB, WC of each cover wiring 32A, 32B, and 32C without changing the area S1 of the lower electrode 16 and the routing length of the cover wiring 32A, 32B, and 32C.

Therefore, in the display device 1 described above, the current transient behaviors of the three segments 20A, 20B, and 20C when the drive current is supplied are the same. That is, the inclination angles of current rise are the same, and the response speeds are the same. Since there is no difference in the transient behaviors of the current supplied to the segments 20, the luminance difference between the segments 20 cannot occur even when the luminance adjustment is performed by the pulse width modulation.

In the display device 1, by aligning all the total areas S of the three segments 20 in the display area 60, although the difference in response speed to the drive current in all the segments 20 decreases, the difference in response speed to the drive current can be decreased by making the total area S be the same in at least two segments 20. For example, by making the total area S of segment 20A (the first lower electrode) be the same as the total area S of segment 20B (the second lower electrode), the difference in response speed to the drive current between the segments 20A and 20B is decreased, and the difference in luminance between the segments 20A and 20B due to the difference in response speed is also decreased.

In addition, in the display device 1 described above, since the second insulating film 14 is an inorganic insulating film formed with an inorganic material, it is easy to make the thickness of the insulating film be thinned. For example, if the second insulating film 14 is formed with SiO₂, a SiO₂ film of approximately 1 micron or less can be obtained by using a film forming technology such as a CVD method, a PVD method, an ALD method or the like. However, because of thinning the second insulating film 14, the stray capacitance generated between the lower electrode 16 and the cover wiring 32, and the upper electrode 50 increases. Even in such a case, by making the total area S which is the sum of the area S1 of the lower electrode 16 and the area S2 of the covering box 32 of each segment be the same, the difference in response speed between the segments 20 is effectively decreased. As a result, the luminance difference between the segments 20 due to the difference in response speed is also effectively decreased.

Instead of aligning the total area S which is the sum of the area S1 of the lower electrode 16 and the area S2 of the cover wiring 32 between the segments 20 as described above, the ratio (S1/S2) between the area S1 of the lower electrode and the area S2 of the cover wiring 32 may be aligned between the segments 20. In this case, since the inclination angle of current rise in each segment 20 becomes the same and the response speeds are the same, the transient behavior of the current when the drive current is supplied approximates to each other. Therefore, even when the luminance adjustment is performed by the pulse width modulation, the luminance difference between the segments 20 is decreased to some extent. In order to make the transient behavior of the current between the segments 20 be closer, the drive current supplied to the segment 20 from the drive circuit 40 may be changed for each segment 20. In this case, the drive current can be changed based on the area of each segment 20 (the same area as the area S1 of the lower electrode 16 in the present embodiment) and the luminance of each segment 20.

In addition, the difference in response speeds to the drive currents can be decreased by making the area ratios (S1/S2) in at least two segments 20 be the same without necessarily aligning the ratio (S1/S2) in the area S1 of the lower electrode and the area S2 of the cover wiring 32 in all the three segments 20 in the display area 60. For example, the difference in response speed to the drive currents between the segments 20A and 20B is decreased by making the area ratio (S1/S2) in the segment 20A (the first lower electrode) be the same as the area ratio (S1/S2) in the segment 20B (the second lower electrode), and thus, the luminance difference between both the segments 20A and 20B due to the difference in response speed is also decreased.

Furthermore, the transient behavior when supplying the drive current to the segment 20 can be matched each other at high accuracy by aligning the total area S which is the sum of the area S1 of the lower electrode 16 and the area S2 of the cover wiring 32 in the segments 20 as described above, and by aligning the ratio (S1/S2) between the area S1 of the lower electrode and the area S2 of the cover wiring 32 in the segments 20, and thus, it is possible to further decrease the difference in response speed to the drive current between the segments and to further decrease the luminance difference between the segments. For example, by matching the response speed to the drive current between the segments 20 at high accuracy, if the luminance adjustment is performed by the pulse width modulation, the luminance difference between the segments 20 can be prevented from occurring.

The display device according to the present disclosure is not limited to the embodiment described above and modifications, and various other modifications can be made.

For example, the number and shape of the segments 20 can be appropriately changed. For example, it may be a mode of 7 segments arrangement in which seven long segments are combined to display the numerals. The second insulating film is not limited to the inorganic insulating film, and may be an organic insulating film formed with an organic film such as novolac resin, acrylic resin, or polyimide. In this case, the second insulating film can be formed by, for example, a spin coating method or a coating method. Furthermore, in the embodiment described above, the lower electrode is the positive electrode and the upper electrode is the negative electrode. However, the lower electrode may be the negative electrode and the upper electrode may be the positive electrode.

Furthermore, the display device is not limited to a see-through structure, but may be a bottom emission structure, a top emission structure, or a dual emission structure. In a case of the bottom emission structure, the second insulating film and the upper electrode can be formed with a non-transparent material, in that case, a non-light-transmitting insulating material (for example, an inorganic insulating material such as SiO₂ or an organic insulating material such as novolac resin) can be used for the second insulating film, and a non-translucent, conductive material (for example, aluminum, silver, or alkaline earth metal (magnesium, calcium, or the like)) can be used for the upper electrode. In addition, in a case of the top emission structure, the substrate, the first insulating film, the second insulating film, and the lower electrode can be formed with a light-impermeable material, and in that case, a light-insensitive insulating material (for example, an inorganic insulating material such as SiO₂ or an organic insulating material such as novolac resin) can be used for the first insulating film and the second insulating film, and a nontransparent conductive material (for example, aluminum, silver, or alkaline earth metal (magnesium, calcium, or the like)) can be used for the lower electrode. In a case of the dual emission structure, the second insulating film can be formed with a light-impermeable material, and in that case, a non-transparent insulating material (for example, an inorganic insulating material such as SiO₂ or an organic insulating material such as novolac resin) can be used for the second insulating film.

What is claimed is:

1. A display device being a segment type display provided with a display area on a substrate, the display device comprising:
a plurality of lower electrodes positioned within the display area on the substrate;
a plurality of organic EL layers provided on the plurality of lower electrodes respectively;
a drive circuit capable to output a drive current to be supplied to each of the organic EL layers provided on the lower electrode;
a plurality of wirings formed on the substrate, the wirings supplying the drive current output from the drive circuit to each of the lower electrodes;
an insulating film covering the wirings, the insulating film formed within the display area and including a plurality of opening portions exposing each of the organic EL layers; and
an upper electrode covering the insulating film and the organic EL layers, the upper electrode formed within the display area,
wherein a sum of an area of a first lower electrode among the plurality of lower electrodes and an area of a first wiring connected to the first lower electrode among the plurality of wirings in the display area is the same as a sum of an area of a second lower electrode different from the first lower electrode among the plurality of lower electrodes and an area of a second wiring connected to the second lower electrode among the plurality of wirings in the display area.

2. The display device according to claim 1, wherein a ratio of the area of the first lower electrode to the area of the first wiring in the display area is the same as a ratio of the area of the second lower electrode to the area of the second wiring in the display area.

3. A display device being a segment type display provided with a display area on a substrate, the display device comprising:
a plurality of lower electrodes positioned within the display area on the substrate;
a plurality of organic EL layers provided on the plurality of lower electrodes respectively;
a drive circuit capable to output a drive current to be supplied to each of the organic EL layers provided on the lower electrode;
a plurality of wirings formed on the substrate, the wirings supplying the drive current output from the drive circuit to each of the lower electrodes;
an insulating film covering the wirings, the insulating film formed within the display area and including a plurality of opening portions exposing each of the organic EL layers; and
an upper electrode covering the insulating film and the organic EL layers, the upper electrode formed within the display area,
wherein a ratio of an area of a first lower electrode among the plurality of lower electrodes to an area of a first wiring connected to the first lower electrode among the plurality of wirings in the display area is the same as a ratio of an area of a second lower electrode different from the first lower electrode among the plurality of lower electrodes to an area of a second wiring connected to the second lower electrode among the plurality of wirings in the display area.

4. The display device according to claim 1, wherein the drive circuit capable of outputting drive currents having current values different from each other to the plurality of lower electrodes.

5. The display device according to claim 1, wherein the insulating film is an inorganic insulating film made of an inorganic material.

6. The display device according to claim 3, wherein the drive circuit capable of outputting drive currents having current values different from each other to the plurality of lower electrodes.

7. The display device according to claim 3, wherein the insulating film is an inorganic insulating film made of an inorganic material.
